(19) United States
(12) Patent Application Publication
(10) Pub. No.: US 2025/0221099 A1
(43) Pub. Date: Jul. 3, 2025

(54) MICRO SEMICONDUCTOR CHIP, DISPLAY TRANSFER STRUCTURE, AND DISPLAY APPARATUS

(71) Applicants: SAMSUNG ELECTRONICS CO., LTD., Suwon-si (KR); KOREA UNIVERSITY RESEARCH AND BUSINESS FOUNDATION, Seoul (KR)

(72) Inventors: Kyungwook HWANG, Suwon-si (KR); Inyeong Kang, Seoul (KR); Gunwoo Noh, Seoul (KR); Soyeon Park, Seoul (KR); Youngtek Oh, Suwon-si (KR); Junsik Hwang, Suwon-si (KR)

(73) Assignees: SAMSUNG ELECTRONICS CO., LTD., Suwon-si (KR); KOREA UNIVERSITY RESEARCH AND BUSINESS FOUNDATION, Seoul (KR)

(21) Appl. No.: 19/003,552

(22) Filed: Dec. 27, 2024

(30) Foreign Application Priority Data
Dec. 28, 2023 (KR) 10-2023-0195358

(51) Int. Cl. H10H 20/819; H10H 20/831; H10H 29/03; H10H 29/24

(52) U.S. Cl. CPC H10H 20/819; H10H 20/831; H10H 29/03; H10H 29/24

(57) ABSTRACT

A micro semiconductor chip includes a semiconductor multilayer and at least one electrode on at least one surface of the semiconductor multilayer, wherein the semiconductor multilayer may have a polygonal planar shape and rounded corners.

### CROSS-REFERENCE TO RELATED APPLICATION

This application is based on and claims priority under 35 U.S.C. § 119 to Korean Patent Application No. 10-2023-0195358, filed on Dec. 28, 2023, in the Korean Intellectual Property Office, the disclosure of which is incorporated by reference herein in its entirety.

### BACKGROUND

### 1. Field

Embodiments of the present disclosure relate to a micro semiconductor chip, a display transfer structure, and a display apparatus.

### 2. Description of Related Art

Liquid crystal displays (LCDs) and organic light-emitting diode (OLED) displays are widely used as display apparatuses. Recently, there has been growing attention to techniques of manufacturing high-resolution display apparatuses using micro semiconductor chips such as micro light-emitting devices. Industrial demand for light-emitting diodes (LEDs) is increasing because LEDs consume a small amount of power and have environmental friendliness, and LEDs have been applied not only to lighting devices and LCD backlights but also to display apparatuses.

When display apparatuses are manufactured using micro light-emitting devices, a method of transferring micro light-emitting devices onto a display substrate is used. The miniaturization of micro-emitting devices and the adoption of large display apparatuses are causes of decreasing productivity and increasing repair process difficulty, and thus, efforts are underway to improve manufacturing yield.

### SUMMARY

Embodiments of the present disclosure include micro semiconductor chips shaped to improve manufacturing yield, a display transfer structure including the micro semiconductor chips, and a display apparatus including the micro semiconductor chips.

According to embodiments of the present disclosure, a micro semiconductor chip is provided and includes: a semiconductor multilayer; and at least one electrode on at least one surface of the semiconductor multilayer, wherein the semiconductor multilayer has an n-polygonal planar shape and n rounded corners, wherein n is an integer greater than or equal to 3.

According to one or more embodiments of the present disclosure, the n rounded corners have a radius of curvature of 0.5 μm or more.

According to one or more embodiments of the present disclosure, the n rounded corners have a radius of curvature that is less than 50% of a length of one side of the semiconductor multilayer.

According to one or more embodiments of the present disclosure, the semiconductor multilayer comprises a first-type semiconductor layer, an active layer, and a second-type semiconductor layer that are sequentially stacked in a first direction, and the n-polygonal planar shape of the semiconductor multilayer is a shape of the semiconductor multilayer in the first direction.

According to one or more embodiments of the present disclosure, a planar size of the first-type semiconductor layer is greater than a planar size of the second-type semiconductor layer.

According to one or more embodiments of the present disclosure, the first-type semiconductor layer is thicker than the second-type semiconductor layer.

According to one or more embodiments of the present disclosure, the first-type semiconductor layer comprises the n rounded corners.

According to one or more embodiments of the present disclosure, the active layer and the second-type semiconductor layer comprise the n rounded corners.

According to one or more embodiments of the present disclosure, the first-type semiconductor layer and the second-type semiconductor layer have a same planar size as each other.

According to one or more embodiments of the present disclosure, the at least one electrode comprises a first electrode and a second electrode that are spaced apart from each other on one surface of the semiconductor multilayer.

According to one or more embodiments of the present disclosure, the at least one electrode comprises a first electrode on a first surface of the semiconductor multilayer and a second electrode on a second surface of the semiconductor multilayer, opposite of the first surface.

According to one or more embodiments of the present disclosure, a length of one side of the micro semiconductor chip is 100 μm or less.

According to embodiments of the present disclosure, a display transfer structure is provided and includes: a substrate comprising a plurality of recesses that are spaced apart from each other; and a plurality of micro semiconductor chips in the plurality of recesses, wherein each of the plurality of micro semiconductor chips comprises: a semiconductor multilayer; and at least one electrode on at least one surface of the semiconductor multilayer, and wherein the semiconductor multilayer has an n-polygonal planar shape and n rounded corners, wherein n is an integer greater than or equal to 3.

According to one or more embodiments of the present disclosure, each of the plurality of recesses has a corner shape that is different from a corner shape of the n rounded corners of the semiconductor multilayer of the plurality of micro semiconductor chips.

According to one or more embodiments of the present disclosure, the n rounded corners have a radius of curvature of 0.5 μm or more.

According to one or more embodiments of the present disclosure, the n rounded corners have a radius of curvature that is less than 50% of a length of one side of the semiconductor multilayer.

According to one or more embodiments of the present disclosure, the semiconductor multilayer comprises a first-type semiconductor layer, an active layer, and a second-type semiconductor layer that are sequentially stacked in a first direction, and the n-polygonal planar shape of the semiconductor multilayer is a shape of the semiconductor multilayer in the first direction.

According to embodiments of the present disclosure, a display apparatus is provided and includes: a driving circuit board; and a plurality of micro semiconductor chips spaced apart from each other on the driving circuit board, wherein each of the plurality of micro semiconductor chips comprises: a semiconductor multilayer; and at least one electrode on at least one surface of the semiconductor multilayer, and wherein the semiconductor multilayer has an n-polygonal planar shape and n rounded corners, wherein n is an integer greater than or equal to 3.

According to one or more embodiments of the present disclosure, the n rounded corners have a radius of curvature of 0.5 μm or more.

According to one or more embodiments of the present disclosure, the n rounded corners have a radius of curvature that is less than 50% of a length of one side of the semiconductor multilayer.

Additional aspects will be set forth in part in the description which follows and, in part, will be apparent from the description, or may be learned by practice of the presented example embodiments of the present disclosure.

### BRIEF DESCRIPTION OF DRAWINGS

The above and other aspects, features, and advantages of example embodiments of the present disclosure will be more apparent from the following description taken in conjunction with the accompanying drawings, in which:

FIG. 1 is a view schematically illustrating a micro semiconductor chip according to an embodiment;

FIG. 2 is a view schematically illustrating a cross-sectional structure of a micro semiconductor chip according to an embodiment;

FIG. 3 is a view schematically illustrating an electrode arrangement of a micro semiconductor chip according to an embodiment;

FIG. 4 is a view schematically illustrating a lateral-surface shape of a micro semiconductor chip according to an embodiment;

FIG. 5 is a perspective view schematically illustrating a micro semiconductor chip according to an embodiment;

FIG. 6A is a view illustrating outer shapes of micro semiconductor chips according to some embodiments;

FIG. 6B is a view illustrating outer shapes of micro semiconductor chips according to some embodiments;

FIG. 6C is a view illustrating outer shapes of micro semiconductor chips according to some embodiments;

FIG. 7 is an enlarged plan view illustrating a corner of a micro semiconductor chip according to an embodiment;

FIG. 8 is an enlarged perspective view illustrating a corner of a micro semiconductor chip according to an embodiment;

FIG. 9 is a view illustrating an operation of transferring micro semiconductor chips according to some embodiments;

FIG. 10 is a view illustrating an operation of transferring micro semiconductor chips according to some embodiments;

FIG. 11 is a view illustrating an operation of transferring micro semiconductor chips according to some embodiments;

FIG. 12 is a view illustrating phenomena that may occur during an operation of transferring micro semiconductor chips according to some embodiments;

FIG. 13 is a view illustrating phenomena that may occur during an operation of transferring micro semiconductor chips according to some embodiments;

FIG. 14 is a view illustrating a simulation in which a micro semiconductor chip collides with another structure;

FIG. 15 is a view illustrating results of the simulation shown in FIG. 14;

FIG. 16 is a plan view illustrating a display transfer structure including a plurality of micro semiconductor chips according to an embodiment;

FIG. 17 is a partial cross-sectional view illustrating a display transfer structure according to an embodiment;

FIG. 18 is a view illustrating a display transfer structure according to some embodiments;

FIG. 19 is a view illustrating a display transfer structure according to some embodiments;

FIG. 20 is a view illustrating a display transfer structure according to an embodiment;

FIG. 21 is a block diagram illustrating an electronic apparatus including a display apparatus according to an embodiment;

FIG. 22 is a view illustrating an example in which an electronic apparatus is applied to a mobile device according to an embodiment;

FIG. 23 is a view illustrating an example in which a display apparatus is applied to a vehicle according to an embodiment;

FIG. 24 is a view illustrating an example in which a display apparatus is applied to augmented reality glasses or virtual reality glasses according to an embodiment;

FIG. 25 is a view illustrating an example in which a display apparatus is applied to large signage according to an embodiment; and

FIG. 26 is a view illustrating an example in which a display apparatus is applied to a wearable display according to an embodiment.

### DETAILED DESCRIPTION

Reference will now be made in detail to non-limiting example embodiments, examples of which are illustrated in the accompanying drawings, wherein like reference numerals refer to like elements throughout. In this regard, the example embodiments may have different forms and should not be construed as being limited to the descriptions set forth herein. Accordingly, the embodiments are described below, by referring to the figures, to explain non-limiting example aspects of the present disclosure. As used herein, the term “and/or” includes any and all combinations of one or more of the associated listed items. Expressions such as “at least one of,” when preceding a list of elements, modify the entire list of elements and do not modify the individual elements of the list.

Hereinafter, micro semiconductor chips, display transfer structures including the micro semiconductor chips, and display apparatuses including the micro semiconductor chips will be described according to various non-limiting example embodiments with reference to the accompanying drawings. In the drawings, the size of each element may be exaggerated for clarity of illustration. It will be understood that although terms such as “first” and “second” may be used herein to describe various components, these components should not be limited by these terms. These terms are only used to distinguish one element from another.

As used herein, singular forms may include plural forms as well unless the context clearly indicates otherwise. It will be further understood that the terms “comprises,” “comprising,” “includes,” and/or “including” used herein specify the presence of stated features or elements, but do not preclude the presence or addition of one or more other features or elements. In the drawings, the size or thickness of each element may be exaggerated for clarity of illustration. Furthermore, it will be understood that when a material layer is referred to as being “on” or “above” a substrate or another layer, it can be directly on the substrate or the other layer, or intervening layers may also be present. Furthermore, in the example embodiments of the present disclosure, a material included in each layer is an example, and another material may be used in addition to or instead of the material.

In the present disclosure, terms such as “unit” or “module” may be used to denote a unit that has at least one function or operation and is implemented with hardware, software, or a combination of hardware and software.

Specific executions described herein are merely examples and do not limit the scope of the present disclosure in any way. For simplicity of description, other functional aspects of conventional electronic configurations, control systems, software and the systems may be omitted. Furthermore, line connections or connection members between elements depicted in the drawings represent functional connections and/or physical or circuit connections by way of example, and in actual applications, they may be replaced or embodied as various additional functional connections, physical connections or circuit connections.

An element referred to with the definite article or a demonstrative pronoun may be construed as the element or the elements even though it has a singular form.

Operations of a method may be performed in any appropriate order unless explicitly described to be limited in terms of order or described to the contrary. In addition, examples or exemplary terms (e.g., “such as” and “etc.”) are used for the purpose of description and are not intended to limit the scope of the present disclosure.

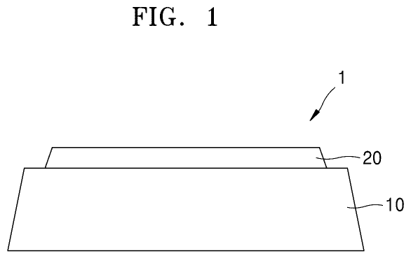

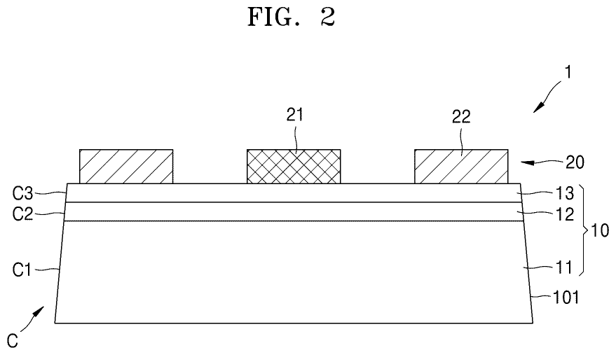

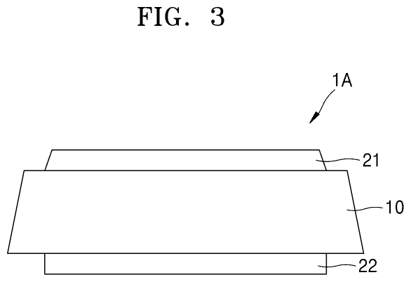

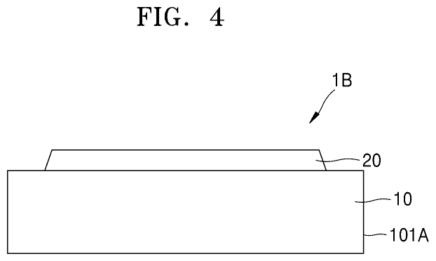

FIG. 1 is a view schematically illustrating a micro semiconductor chip 1 according to an embodiment. FIG. 2 is a view schematically illustrating a cross-sectional structure of the micro semiconductor chip 1 according to an embodiment. FIG. 3 is a view schematically illustrating another arrangement example of an electrode 20 of a micro semiconductor chip 1A according to an embodiment. FIG. 4 is a view schematically illustrating a shape of a lateral surface 101A of a micro semiconductor chip 1B according to an embodiment.

Referring to FIGS. 1 and 2, according to embodiments, examples of the micro semiconductor chip 1 may include various types of semiconductor chips having a micro size. The micro size may be about 1000 μm or less. The micro size may be about 200 μm or less. The micro size may be about 100 μm or less. In other words, the length of one side of the micro semiconductor chip 1 may be about 1000 μm or less. The length of one side of the micro semiconductor chip 1 may be about 200 μm or less. The length of one side of the micro semiconductor chip 1 may be about 100 μm or less.

The micro semiconductor chip 1 may be a light-emitting unit. However, the type of the micro semiconductor chip 1 is not limited thereto and may vary. For example, the micro semiconductor chip 1 may be at least one selected from among a light-emitting diode (LED), a complementary metal-oxide semiconductor (CMOS), a CMOS image sensor (CIS), a vertical-cavity surface-emitting laser (VCSEL), a photo diode (PD)., a memory device, and a two-dimensional (2D) material device having a 2D material. The 2D material may be graphene or a carbon nano tube (CNT).

The micro semiconductor chip 1 may include a semiconductor multilayer 10 and at least one electrode 20.

The semiconductor multilayer 10 includes a first-type semiconductor layer 11, an active layer 12, and a second-type semiconductor layer 13 that are sequentially arranged in a first direction (e.g., a vertical direction). The first direction may be defined as a stacking direction.

The first-type semiconductor layer 11 may be an n-type semiconductor layer. The first-type semiconductor layer 11 may include an n-type semiconductor selected from Group III-V semiconductors, for example, n-GaN. The first-type semiconductor layer 11 may have a single-layer or multilayer structure. For example, the first-type semiconductor layer 11 may have a multilayer structure in which a buffer layer and a plurality of n-type semiconductor layers having different doping concentrations are stacked.

The active layer 12 may be provided on an upper surface of the first-type semiconductor layer 11. Light may be generated when electrons and holes combine with each other in the active layer 12. The active layer 12 may have a multi-quantum well (MQW) or single-quantum well (SQW) structure. The active layer 12 may include a Group III-V semiconductor, for example, GaN.

The second-type semiconductor layer 13 may be provided on an upper surface of the active layer 12. The second-type semiconductor layer 13 may be, for example, a p-type semiconductor layer. The second-type semiconductor layer 13 may include a p-type semiconductor selected from Group III-V semiconductors, for example, p-GaN. The second-type semiconductor layer 13 may have a single-layer or multilayer structure. Alternatively, when the first-type semiconductor layer 11 is a p-type semiconductor layer, the second-type semiconductor layer 13 may be an n-type semiconductor layer.

The electrode 20 may be disposed on at least one surface of the semiconductor multilayer 10. The electrode 20 may include a first electrode 21 and a second electrode 22 that are arranged on a surface of the semiconductor multilayer 10 and are apart from each other. For example, the first electrode 21 may be disposed on a center portion of an upper surface of the semiconductor multilayer 10, and the second electrode 22 may be disposed on an outer portion of the upper surface of the semiconductor multilayer 10. For example, the first electrode 21 may be disposed on a center portion of an upper surface of the second-type semiconductor layer 13, and the second electrode 22 may be disposed on an outer portion of the upper surface of the second-type semiconductor layer 13. According to embodiments, the first electrode 21 may be electrically connected to the first-type semiconductor layer 11, and the second electrode 22 may be electrically connected to the second-type semiconductor layer 13.

However, the configuration and arrangement of the electrode 20 are not limited thereto and may vary. According to an embodiment, for example, in the micro semiconductor chip 1A, the first electrode 21 and the second electrode 22 may be respectively disposed on upper and lower surfaces of the semiconductor multilayer 10 as shown in FIG. 3. In other words, the electrode 20 may include a first electrode 21 disposed on a surface of the semiconductor multilayer 10 and a second electrode 22 disposed on another surface side of the semiconductor multilayer 10.

The electrode 20 may include a conductive metal. For example, the electrode 20 may include at least one selected from among aluminum (Al), gold (Au), platinum (Pt), molybdenum (Mo), copper (Cu), silver (Ag), and zinc (Zn).

The semiconductor multilayer 10 may have a size varying in the stacking direction. A lateral surface 101 of the semiconductor multilayer 10 may be inclined with respect to the stacking direction. However, the shape of the lateral surface 101 of the semiconductor multilayer 10 is not limited thereto and may vary depending on a manufacturing method or the like. According to an embodiment, for example, in the micro semiconductor chip 1B, the lateral surface 101A of the semiconductor multilayer 10 may have a constant size in the stacking direction as shown in FIG. 4. In this case, the planar size of the first-type semiconductor layer 11 and the planar size of the second-type semiconductor layer 13 may be equal to each other.

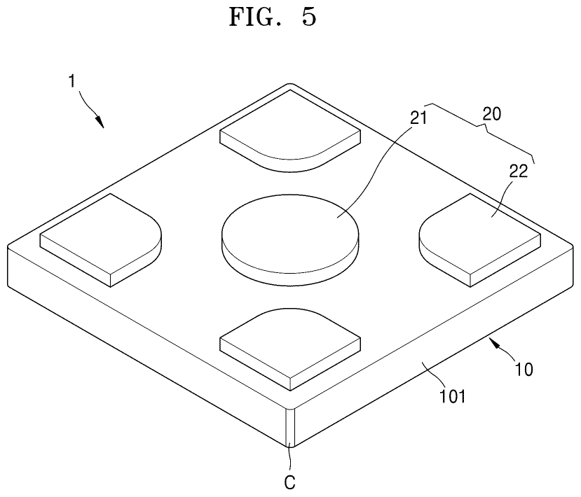

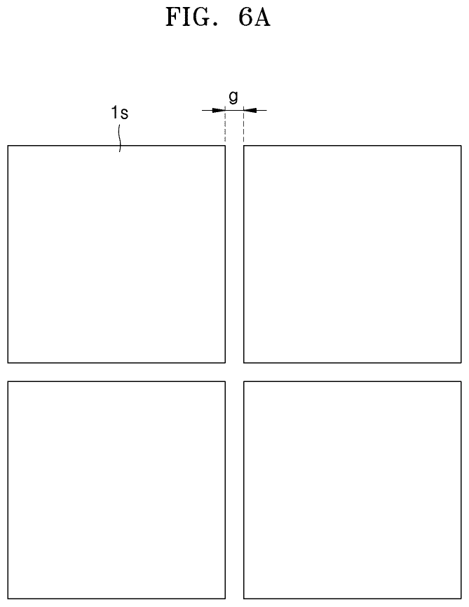

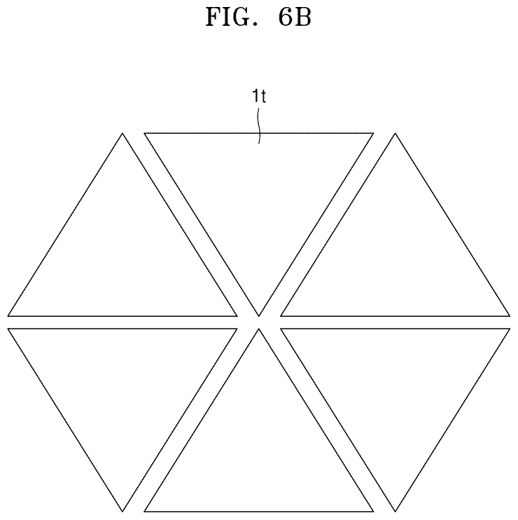

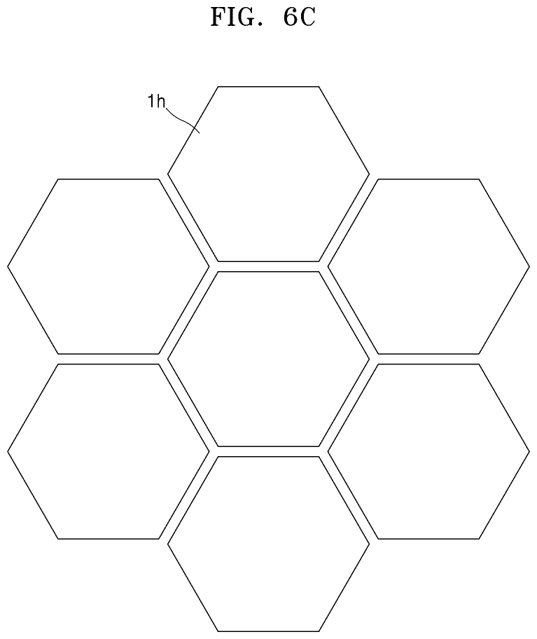

FIG. 5 is a perspective view schematically illustrating a micro semiconductor chip 1 according to an embodiment. FIGS. 6A to 6C are views illustrating outer shapes of micro semiconductor chips 1 according to embodiments. For ease of illustration, FIGS. 5 and 6 illustrate a structure in which the size of a lateral surface 101 of the micro semiconductor chip 1 is constant in the stacking direction. However, embodiments are not limited thereto.

Referring to FIG. 5, the micro semiconductor chip 1 of the embodiment may have a polygonal planar shape. For example, a semiconductor multilayer 10 of the micro semiconductor chip 1 may have a polygonal planar shape. For example, the semiconductor multilayer 10 may have an n-polygonal planar shape. Here, n may be an integer greater than or equal to 3. For example, the semiconductor multilayer 10 may have a triangular, tetragonal, or hexagonal planar shape. Here, the planar shape of the semiconductor multilayer 10 may refer to a shape of the semiconductor multilayer 10 viewed in the stacking direction.

Referring to FIGS. 6A to 6C, when micro semiconductor chips 1 have a polygonal planar shape, the manufacturing yield of the micro semiconductor chips 1 may be improved. For example, as shown in FIG. 6A, when a plurality of tetragonal micro semiconductor chips 1s are formed on one wafer, the tetragonal micro semiconductor chips 1s may be arranged with one side facing another side, and thus, gaps g between the tetragonal micro semiconductor chips 1s may be reduced. As shown in FIGS. 6B and 6C, even when micro semiconductor chips 1t and 1h have triangular and hexagonal planar shapes, gaps between the micro semiconductor chips 1t and 1h may be reduced. Therefore, when micro semiconductor chips 1 are designed to have a polygonal planar shape, portions discarded in a process of producing the micro semiconductor chips 1 may be reduced, and thus, the manufacturing yield of the micro semiconductor chips 1 may be improved.

However, when micro semiconductor chips 1 have a polygonal planar shape, corners C (see FIG. 5) of the micro semiconductor chips 1 may be vulnerable to damage. For example, when a large number of micro semiconductor chips 1 are transferred during an operation of manufacturing a display apparatus or the like, corners C of semiconductor multilayers 10 of the micro semiconductor chips 1 may be vulnerable to damage.

Thus, embodiments may provide a structure for preventing or reducing damage to a plurality of micro semiconductor chips 1 during a mass transfer operation.

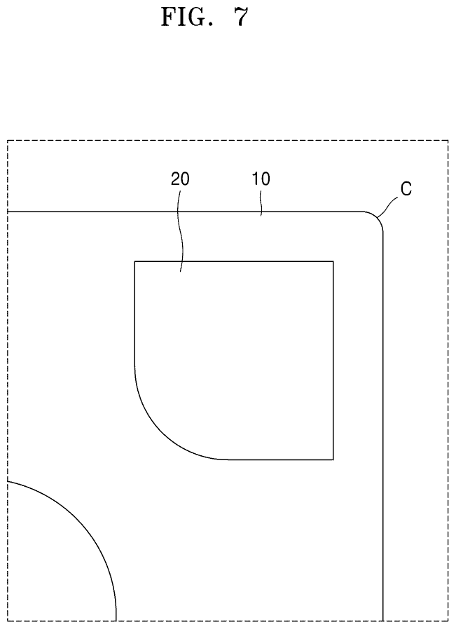

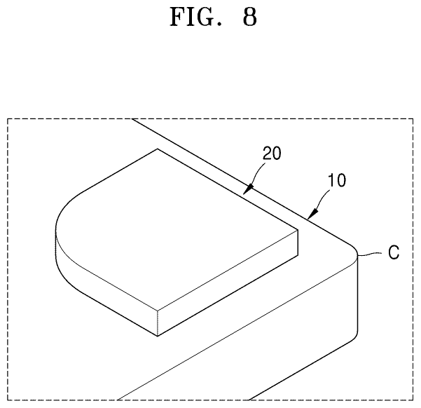

FIG. 7 is an enlarged plan view illustrating a corner C of the micro semiconductor chip 1 according to an embodiment, and FIG. 8 is an enlarged perspective view illustrating the corner C of the micro semiconductor chip 1 according to an embodiment.

Referring to FIGS. 5, 7, and 8, according to an embodiment, the semiconductor multilayer 10 of the micro semiconductor chip 1 may have a polygonal planar shape and rounded corners C. In other words, the semiconductor multilayer 10 of the micro semiconductor chip 1 may have an n-polygonal planar shape (n is an integer of 3 or more), and n corners C of the semiconductor multilayer 10 may be rounded.

The planar shape of the semiconductor multilayer 10 has n line segments and n corners C. The n line segments include straight sections, and the n corners C include curved sections that each connect adjacent straight sections to each other. The angles of the curved sections may continuously vary to connect the straight sections extending at different angles to each other

The corners C of the semiconductor multilayer 10, which are rounded, may have a predetermined radius of curvature. For example, the radius of curvature of the corners C may be about 0.5 μm or more. For example, the radius of curvature of the corners C may be about 1 μm or more. For example, the radius of curvature of the corners C may be about 2 μm or more. For example, the radius of curvature of the corners C may be about 1.25% or more of the length of one side of the semiconductor multilayer 10. For example, the radius of curvature of the corners C may be about 2.5% or more of the length of one side of the semiconductor multilayer 10. For example, the radius of curvature of the corners C may be less than 50% of the length of one side of the semiconductor multilayer 10. Herein, the length of one side may be defined as the length of a side adjacent to a corresponding corner C.

All the corners C of the semiconductor multilayer 10, which are planar, may be rounded. The radius of curvature of all the corners C of the semiconductor multilayer 10 may be the same. In other words, when the planar shape of the semiconductor multilayer 10 is n-polygonal (n is 3 or more), the n corners C of the semiconductor multilayer 10 may have the same radius of curvature. However, the radii of curvature of all the corners C of the semiconductor multilayer 10 are not necessarily the same and may vary depending on stacking positions, materials, or the like.

According to an embodiment, all the corners C of semiconductor multilayers 10 of micro semiconductor chips 1 may be rounded, and thus, even when some corners C collide with surrounding structures as the micro semiconductor chips 1 rotate or tilt during an operation of manufacturing a display apparatus, for example, during an operation of transferring the micro semiconductor chips 1, damage to the corners C may be prevented or reduced.

Referring again to FIG. 2, the semiconductor multilayer 10 may a size varying in the stacking direction. The lateral surface 101 of the semiconductor multilayer 10 may be inclined with respect to the stacking direction. For example, the size of the semiconductor multilayer 10 may decrease in the stacking direction. For example, in the semiconductor multilayer 10, the first-type semiconductor layer 11 may be the largest, and the second-type semiconductor layer 13 may be the smallest. For example, in the semiconductor multilayer 10, the length of one side of the first-type semiconductor layer 11 may be the largest, and the length of one side of the second-type semiconductor layer 13 may be the smallest.

In the semiconductor multilayer 10, the first-type semiconductor layer 11 may be the thickest. The thickness of the first-type semiconductor layer 11 may be greater than about ½ of the total thickness of the semiconductor multilayer 10. The thickness of the first-type semiconductor layer 11 may be greater than or equal to about ⅔ of the total thickness of the semiconductor multilayer 10.

Layers of the semiconductor multilayer 10 may have different thicknesses. For example, the thickness of the first-type semiconductor layer 11 may be greater than the thickness of the second-type semiconductor layer 13. For example, the thickness of the first-type semiconductor layer 11 may be about two or more times the thickness of the second-type semiconductor layer 13.

As described above, some layers of the semiconductor multilayer 10 may be larger and thicker than other layers. For example, in the semiconductor multilayer 10, the planar size of the first-type semiconductor layer 11 may be the greatest, and the thickness of the first-type semiconductor layer 11 may be the greatest. As described above, among the layers of the semiconductor multilayers 10, a relatively large and thick layer, for example, the first-type semiconductor layer 11, has the highest probability of being exposed to collision during an operation of transferring a large number of micro semiconductor chips 1.

Thus, according to an embodiment, in the micro semiconductor chip 1, rounded corners C may be provided on the first-type semiconductor layer 11. In other words, the first-type semiconductor layer 11 may have a polygonal planar shape having corners C1 that are rounded. As described above, the corners C1 of the first-type semiconductor layer 11 that is relatively large and thick are rounded, thereby reducing the probability of the micro semiconductor chip 1 being damaged during a transfer operation.

Corners C that are rounded may be formed on each of the layers of the semiconductor multilayer 10. For example, the first-type semiconductor layer 11, the active layer 12, and the second-type semiconductor layer 13 of the semiconductor multilayer 10 may all have a planar shape with corners C1, C2, and C3 that are rounded. As described above, in addition to the first-type semiconductor layer 11, other layers of the semiconductor multilayer 10 may also have corners C2 and C3 that are rounded, and thus, the probability of the micro semiconductor chip 1 being damaged during a transfer operation may be further lowered.

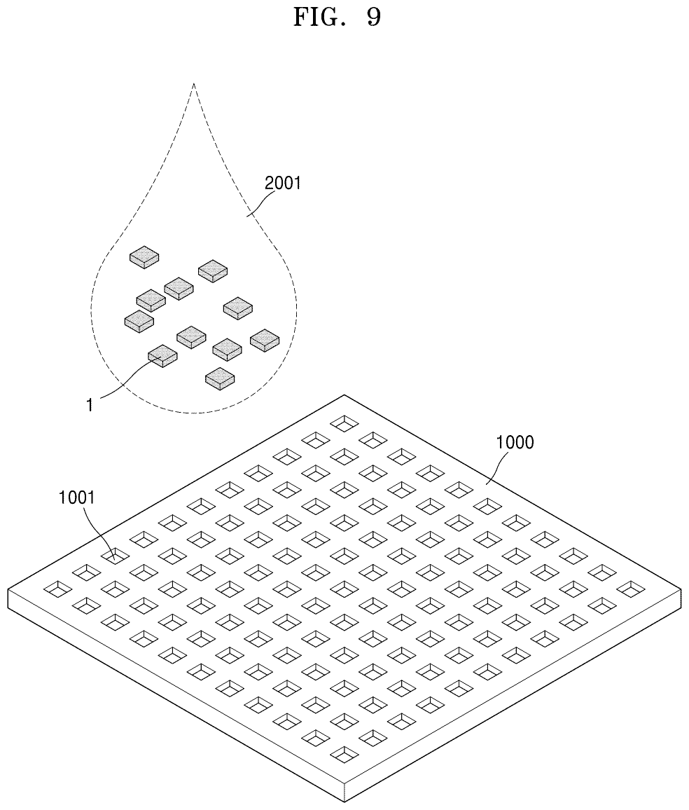

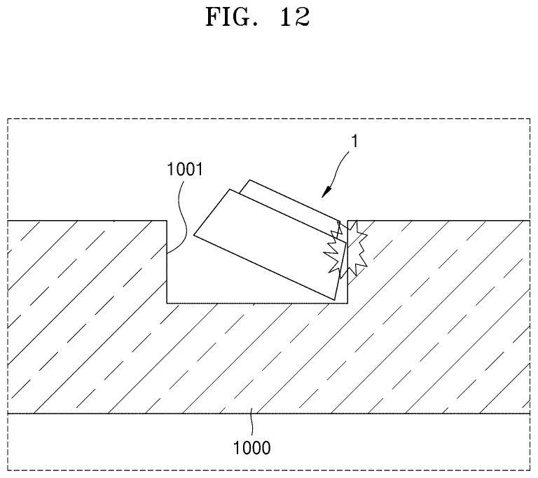

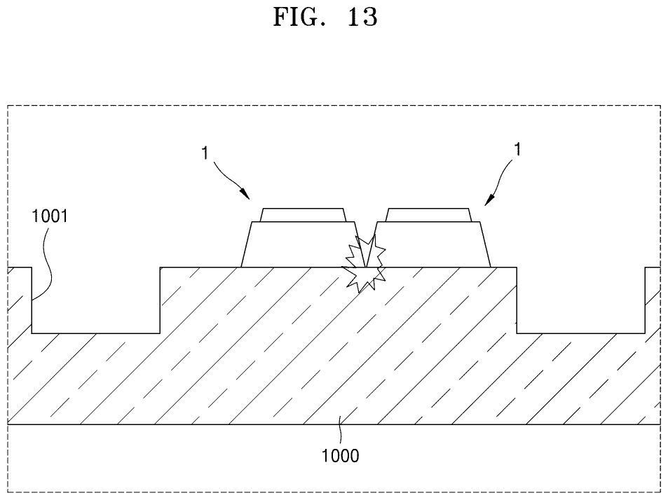

FIGS. 9 to 11 are views illustrating an operation of transferring micro semiconductor chips 1 according to embodiments. FIGS. 12 and 13 are views illustrating phenomena that may occur during an operation of transferring micro semiconductor chips 1 according to embodiments.

In an operation of manufacturing a display apparatus according to an embodiment, a plurality of micro semiconductor chips 1 may be arranged at predetermined intervals on a substrate 1000. In this case, for example, a fluidic self-assembly (FSA) method may be used to insert the plurality of the micro semiconductor chip 1 into a plurality of recesses 1001 of the substrate 1000.

For example, referring to FIG. 9, the micro semiconductor chips 1 may be supplied to the substrate 1000 in which the recesses 1001 are provided.

The substrate 1000 may include the recesses 1001 configured to receive the micro semiconductor chips 1. For example, as shown in FIG. 9, the recesses 1001 may have the same shape and size. However, the shape of the recesses 1001 is not limited thereto and may vary according to the size and shape of the micro semiconductor chips 1. For example, according to an embodiment, when the micro semiconductor chips 1 have different sizes and shapes, the recesses 1001 may have different shapes and/or sizes.

The substrate 1000 may be a transfer substrate for transferring the micro semiconductor chips 1. However, the substrate 1000 may not be a transfer substrate, and in some cases, the substrate 1000 may be a driving circuit board of the display apparatus.

A liquid 2001 may be supplied to supply the micro semiconductor chips 1 to the substrate 1000. The micro semiconductor chips 1 may be supplied to the substrate 1000 together with the liquid 2001, or the liquid 2001 and the micro semiconductor chip 1 may be separately supplied to the substrate 1000. For example, the micro semiconductor chips 1 and the liquid 2001 may be supplied to the substrate 1000 as a suspension in which the micro semiconductor chips 1 and the liquid 2001 are mixed with each other. The liquid 2001 may be supplied by at least one method selected from among a spray method, a dispensing method, an inkjet dot method, and a method of allowing the liquid 2001 to flow onto a transfer substrate.

The liquid 2001 may include at least one selected from among water, ethanol, alcohol, polyol, ketone, halocarbon, acetone, a flux, and an organic solvent.

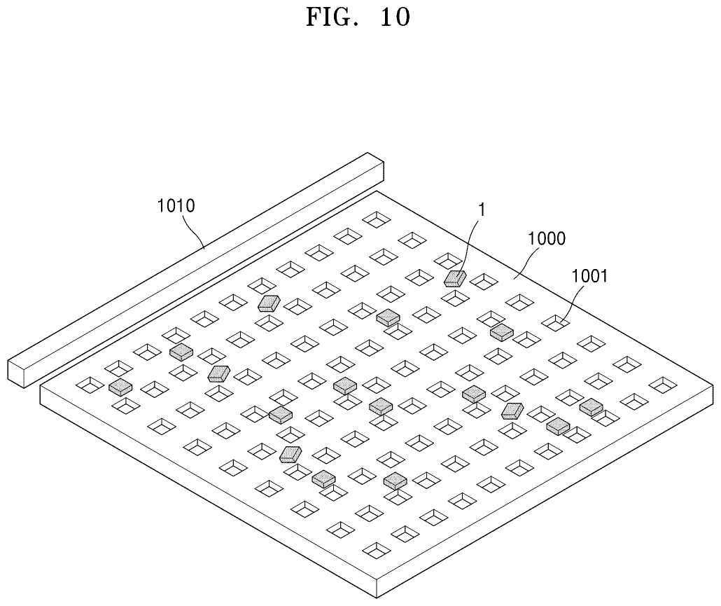

Referring to FIG. 10, after the micro semiconductor chips 1 are supplied to the substrate 1000, the substrate 1000 may be scanned with an absorber 1010 capable of absorbing the liquid 2001.

The substrate 1000 may be scanned while the absorber 1010 presses the substrate 1000 by pressure. The scanning may include bringing the absorber 1010 into contact with the substrate 1000 and passing the absorber 1010 over the recesses 1001. During the scanning, the liquid 2001 may be absorbed into the absorber 1010.

For example, the scanning may be performed in a regular or irregular manner by various methods including at least one selected from among a sliding method, a rotating method, a translating method, a reciprocating method, a rolling method, a spinning method, and a rubbing method. Alternatively, the scanning may include at least one selected from among rotation, translation, rolling, and spinning of the substrate 1000. Alternatively, the scanning may be performed through a cooperative operation of the absorber 1010 and the substrate 1000.

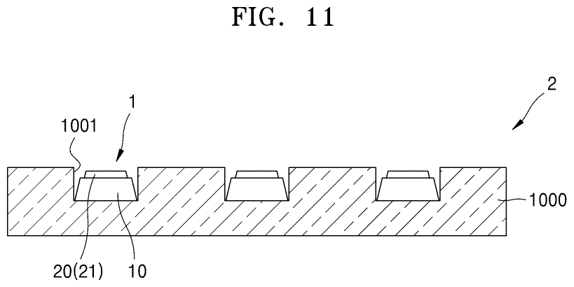

During the scanning, the micro semiconductor chips 1 may be pushed and moved by the absorber 1010. While the micro semiconductor chips 1 are moved by the absorber 1010, the micro semiconductor chip 1 may be inserted into the recesses 1001 formed in the substrate 1000. Therefore, as shown in FIG. 11, the micro semiconductor chips 1 may be arranged at predetermined intervals as the micro semiconductor chips 1 are inserted into the recesses 1001 that are provided in the substrate 1000 at the predetermined intervals.

However, as described above, in the operation of supplying the micro semiconductor chips 1 to the substrate 1000 or inserting the micro semiconductor chips 1 into the recesses 1001, the micro semiconductor chips 1 may collide with surrounding structures or with each other. For example, as shown in FIG. 12, in the operation of inserting the micro semiconductor chips 1 into the recesses 1001 of the substrate 1000, a lateral surface 101 of a micro semiconductor chip 1 may collide with an inner side of a recess 1001 of the substrate 1000. For example, as shown in FIG. 13, in the operation of supplying the micro semiconductor chips 1 to the substrate 1000 or moving the micro semiconductor chips 1 on the substrate 1000 by the absorber 1010 or the like, a lateral surface 101 of a micro semiconductor chip 1 may collide with a lateral surface 101 of an adjacent one of the micro semiconductor chips 1.

When the micro semiconductor chips 1 collide with surrounding structures as described above, an impact force may be applied to the lateral surfaces 101 of the micro semiconductor chips 1. For example, in the planar shape of the micro semiconductor chips 1, impact force may be maximal at the corners C of the micro semiconductor chips 1 because the impact force is concentrated much more in narrower regions, that is, in the corners C of the micro semiconductor chips 1 than in the other regions of the micro semiconductor chips 1. When the maximal impact force acting on the corners C of the micro semiconductor chips 1 is greater than a certain value, the micro semiconductor chips 1 may be broken.

According to an embodiment, the corners C of the semiconductor multilayers 10 of the micro semiconductor chips 1 are rounded, and thus, an impact force greater than or equal to the certain value may not be applied to one point.

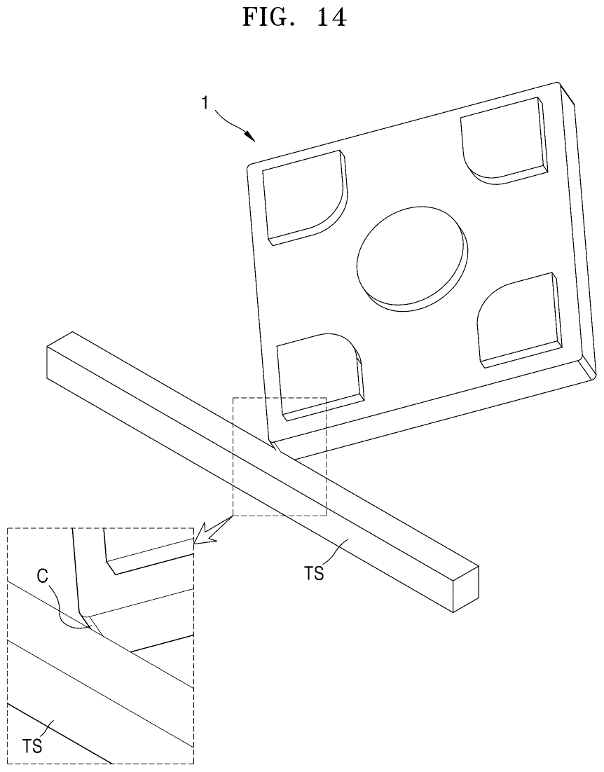

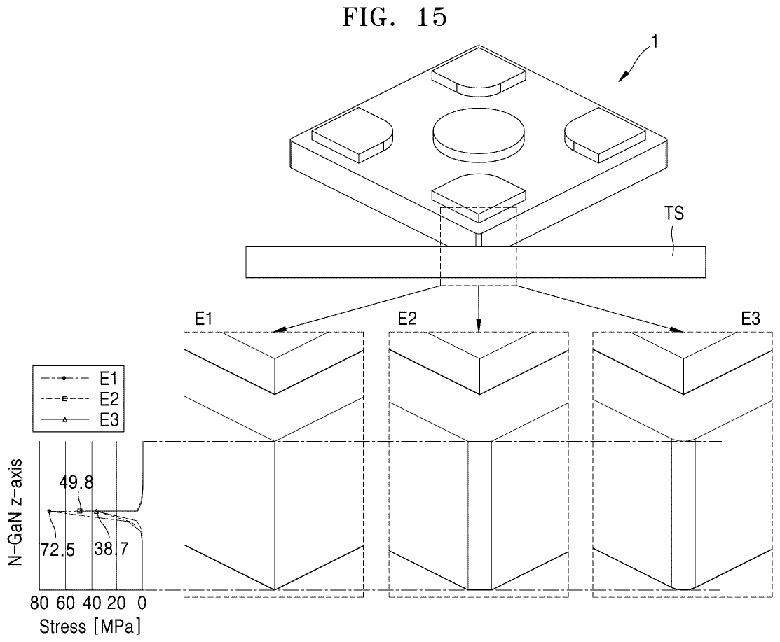

FIG. 14 is a view illustrating a simulation in which a micro semiconductor chip 1 collides with another structure, and FIG. 15 is a view illustrating results of the simulation shown in FIG. 14.

Referring to FIGS. 14 and 15, in Example 1 (E3), a semiconductor multilayer 10 of a micro semiconductor chip 1 has a square planar shape, a line segment length of 40 μm, a radius of curvature of 0.5 μm at a corner C thereof. The micro semiconductor chip 1 was forced to collide with a target substrate TS at a speed of 20 cm/s to apply an impact force to the corner C of the micro semiconductor chip 1, and an impulse at a collision portion was measured.

A micro semiconductor chip 1 of Comparative Example 1 (E1) has the same structure as the micro semiconductor chip 1 of Example 1 (E3) and was simulated under the same conditions as the micro semiconductor chip 1 of Example 1 (E3), except that a corner C of a semiconductor multilayer 10 of the micro semiconductor chip 1 of Comparative Example 1 (E1) is angled at 90 degrees.

A micro semiconductor chip 1 of Comparative Example 2 (E2) has the same structure as the micro semiconductor chip 1 of Example 1 (E3) and was simulated under the same conditions as the micro semiconductor chip 1 of Example 1 (E3), except that a corner C of a semiconductor multilayer 10 of the micro semiconductor chip 1 of Comparative Example 2 (E2) connects adjacent line segments to each other with a straight segment instead of a rounded segment.

When the micro semiconductor chips 1 of Example 1 (E3), Comparative Example 1 (E1), and Comparative Example 2 (E2) were impacted in a condition in which the corners C of the micro semiconductor chips 1 had different shapes, a maximum impulse (or maximum stress) applied to the corner C of the micro semiconductor chip 1 of Example 1 (E3) was 38.7 Mpa, a maximum impulse applied to the corner C of the micro semiconductor chip 1 of Comparative Example 1 (E1) was 72.5 Mpa, and a maximum impulse applied to the corner C of the micro semiconductor chip 1 of Comparative Example 2 (E2) was 49.8 Mpa. In Comparative Example 2 (E2), the maximum impulse or a similar impulse, that is, a large impact force, was observed at two points on both sides of the corner C.

The results above show that even when the same impact force is applied to the same position, difference maximum impulses act on the micro semiconductor chips 1 depending on the shapes of the corners C. For example, it could be understood that when a micro semiconductor chip 1 has a corner C that is roudned as in Example 1 (E3), the maximum impulse acting on the micro semiconductor chip 1 reduces by about 47% compared to the maximum impulse acting on a micro semiconductor chip 1 having a corner C that is angled as in Comparative Example 1 (E1). In addition, it could be understood that when a micro semiconductor chip 1 has a rounded corner C as in Example 1 (E3), the maximum impulse acting on the micro semiconductor chip 1 reduces, and a region in which a great impact force acts on the micro semiconductor chip 1 does not increase unlike in Comparative Example 2 (E2) in which a corner C that is flat is provided.

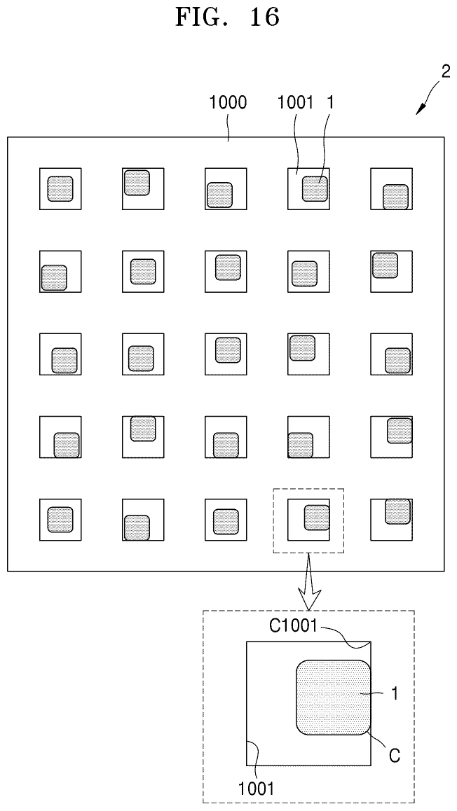

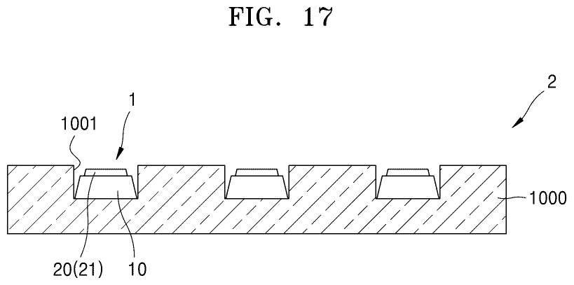

FIG. 16 is a plan view illustrating a display transfer structure 2 including a plurality of micro semiconductor chips 1 according to an embodiment, and FIG. 17 is a partial cross-sectional view illustrating the display transfer structure 2 according to an embodiment.

Referring to FIGS. 16 and 17, according to an embodiment, the display transfer structure 2 may include a substrate 1000 and the micro semiconductor chips 1 arranged apart from each other on the substrate 1000.

The substrate 1000 may include a plurality of recesses 1001 arranged apart from each other. The substrate 1000 may be a transfer substrate configured to be used in an intermediate operation while the display transfer structure 2 transfers the micro semiconductor chips 1. However, the substrate 1000 is not limited thereto and may be a driving circuit board.

The recesses 1001 may have a shape corresponding to the shape of the micro semiconductor chips 1. For example, the planar shape of the recesses 1001 may correspond to the planar shape of the micro semiconductor chips 1. For example, when the recesses 1001 has a tetragonal planar square, the micro semiconductor chips 1 may have a tetragonal planar shape.

The micro semiconductor chips 1 may be disposed in the recesses 1001. Each of the micro semiconductor chips 1 may include at least one electrode 20 on a surface facing an upper opening of a recess 1001. In addition, each of the micro semiconductor chip 1 may not include an electrode on a surface facing a bottom of a recess 1001.

The at least one electrode 20 may be, for example, a negative electrode. Alternatively, the at least one electrode 20 may be, for example, a positive electrode. The at least one electrode 20 may be positioned toward the upper opening of the recess 1001.

The micro semiconductor chips 1 may be arranged in the recesses 1001 in a manner such that one micro semiconductor chip 1 may be disposed in one recess 1001. However, the arrangement of the micro semiconductor chips 1 is not limited thereto, and a plurality of micro semiconductor chips 1 may be arranged in each recess 1001.

Corners C of the micro semiconductor chips 1 and corners C1001 of the recesses 1001 may have different shapes. For example, when each of the corners C of the micro semiconductor chips 1 has a round shape, each of the corners C1001 of the recesses 1001 may not have a round shape. For example, the corners C1001 of the recesses 1001 may have an angled shape.

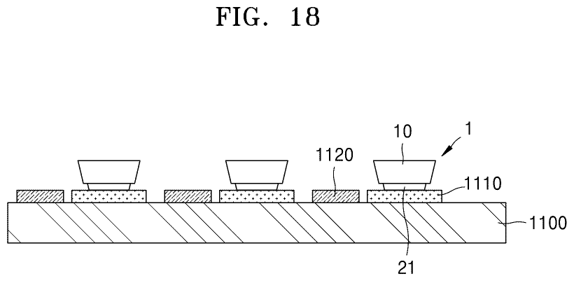

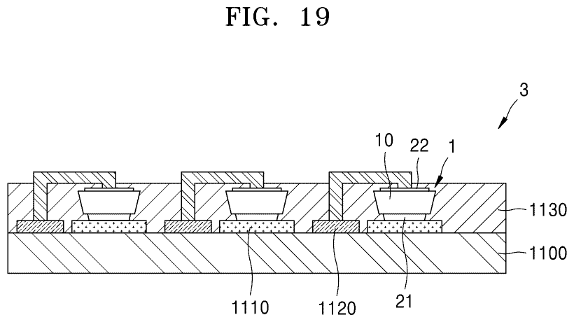

Referring to FIG. 18, the micro semiconductor chips 1 arranged on the substrate 1000 shown in FIG. 17 may be transferred to a driving circuit board 1100. The micro semiconductor chips 1 may be arranged on the driving circuit board 1100 at a distance from each other. The driving circuit board 1100 and the micro semiconductor chips 1 may form a display apparatus 3 (refer to FIG. 19).

A first circuit 1110 and a second circuit 1120 may be provided on the driving circuit board 1100. When the micro semiconductor chips 1 are transferred to the driving circuit board 1100, first electrodes 21 of the micro semiconductor chips 1 may be connected to the first circuit 1110.

Referring to FIG. 19, an insulating layer 1130 may be provided on the structure shown in FIG. 18. Then, second electrodes 22 may be formed on the micro semiconductor chips 1 by patterning the insulating layer 1130. In addition, the second electrodes 22 may be connected to the second circuit 1120.

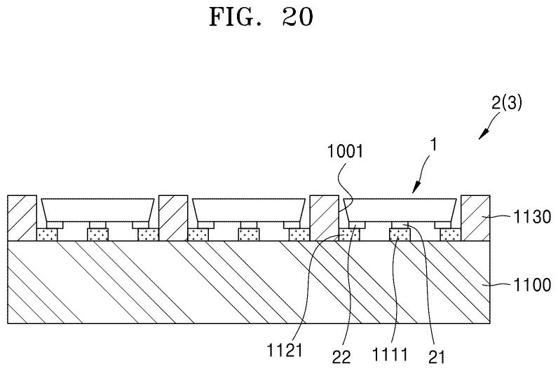

In another example, as shown in FIG. 20, a plurality of micro semiconductor chips 1 may be transferred to a driving circuit board 1100. In this case, one or more electrodes (e.g., first electrodes 1111 and second electrodes 1121) may be provided in each of recesses 1001 of the driving circuit board 1100, and electrodes (e.g., first electrodes 21 and second electrodes 22) corresponding to the electrodes (e.g., first electrodes 1111 and second electrodes 1121) may be provided on a lower portion of each of the micro semiconductor chips 1.

For example, first electrodes 1111 and second electrodes 1121 may be arranged at predetermined intervals in the recesses 1001, and a plurality of electrodes, that is, the first electrodes 21 and the second electrodes 22, may be provided on the lower portions of the micro semiconductor chips 1.

The display transfer structure 2 may be applied to the display apparatus 3. For example, the display transfer structure 2 may be used as a backlight unit of the display apparatus 3.

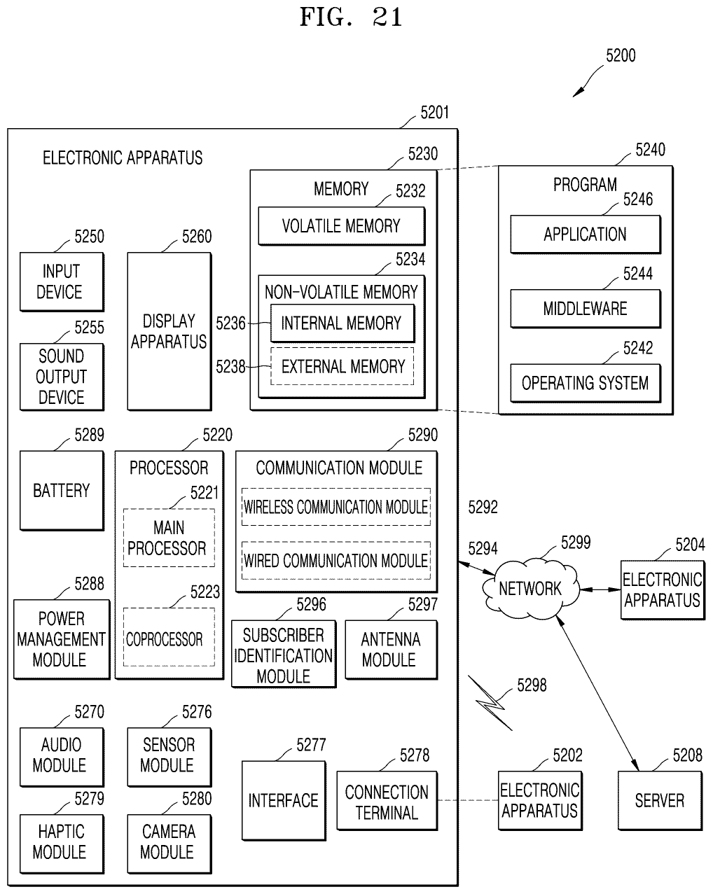

FIG. 21 is a block diagram illustrating an electronic apparatus 5201 including a display apparatus 5260 according to an embodiment.

Referring to FIG. 21, the electronic apparatus 5201 may be provided in a network environment 5200. In the network environment 5200, the electronic apparatus 5201 may communicate with another electronic apparatus 5202 through a first network 5298 (e.g., a short-range wireless communication network) or may communicate with another electronic apparatus 5204 and/or a server 5208 through a second network 5299 (e.g., a long-range wireless communication network). The electronic apparatus 5201 may communicate with the electronic apparatus 5204 through the server 5208. The electronic apparatus 5201 may include a processor 5220, a memory 5230, an input device 5250, a sound output device 5255, the display apparatus 5260, an audio module 5270, a sensor module 5276, an interface 5277, a haptic module 5279, a camera module 5280, a power management module 5288, a battery 5289, a communication module 5290, a subscriber identification module 5296, and/or an antenna module 5297. Some of the components of the electronic apparatus 5201 may be omitted, or other components may be added to the electronic apparatus 5201. Some of the components may be implemented as one integrated circuit. For example, the sensor module 5276 (e.g., a fingerprint sensor, an iris sensor, or an illuminance sensor) may be embedded in the display apparatus 5260 (e.g., a display).

The processor 5220 may execute software (e.g., a program 5240) to control one or more other components (e.g., hardware or software components) of the electronic apparatus 5201 which are connected to the processor 5220, and the processor 5220 may perform various data processing or operations. As part of data processing or computation, the processor 5220 may load commands and/or data received from other components (e.g., the sensor module 5276, the communication module 5290, etc.) on a volatile memory 5232, process the commands and/or data stored in the volatile memory 5232, and store resulting data in a non-volatile memory 5234. The processor 5220 may include: a main processor 5221 (e.g., a central processing unit, an application processor, etc.); and a coprocessor 5223 (e.g., a graphics processing unit, an image signal processor, a sensor hub processor, a communication processor, etc.) that may be operated independently or in conjunction with the main processor 5221. The coprocessor 5223 may consume less power than the main processor 5221 and may perform a specialized function.

The coprocessor 5223 may control functions and/or states related to some of the components (e.g., the display apparatus 5260, the sensor module 5276, and the communication module 5290) of the electronic apparatus 5201, instead of the main processor 5221 while the main processor 5221 is in an inactive state (sleep mode) or together with the main processor 5221 while the main processor 5221 is in an active state (application-execution mode). The coprocessor 5223 (e.g., an image signal processor, a communication processor, etc.) may be implemented as part of a functionally related component (e.g., the camera module 5280 or the communication module 5290).

The memory 5230 may store various pieces of data required by the components (e.g., the processor 5220, the sensor module 5276, etc.) of the electronic apparatus 5201. For example, the data may include: software (e.g., the program 5240); and instruction input data and/or output data which are related to the software. The memory 5230 may include the volatile memory 5232 and/or the non-volatile memory 5234.

The program 5240 may be stored as software in the memory 5230 and may include an operating system 5242, middleware 5244, and/or an application 5246.

The input device 5250 may receive, from outside the electronic apparatus 5201 (e.g., a user), commands and/or data to be used in the components (e.g., the processor 5220) of the electronic apparatus 5201. The input device 5250 may include a remote controller, a microphone, a mouse, a keyboard, and/or a digital pen (e.g., a stylus pen).

The sound output device 5255 may output a sound signal to the outside of the electronic apparatus 5201. The sound output device 5255 may include a speaker and/or a receiver. The speaker may be used for general purposes such as multimedia playback or recorded data playback, and the receiver may be used to receive incoming calls. The receiver may be integrated as a part of the speaker or may be implemented as an independent separate device.

The display apparatus 5260 may provide information to the outside of the electronic apparatus 5201 in a visual manner. The display apparatus 5260 may include a device such as a display, a hologram device, or a projector, and a control circuit for controlling the device. The display apparatus 5260 may include the display transfer structure 2 described with reference to FIGS. 17 to 20. The display apparatus 5260 may include: touch circuitry configured to detect touches; and/or a sensor circuit (e.g., a pressure sensor) configured to measure the magnitudes of forces generated by touches.

The audio module 5270 may convert a sound into an electric signal or may conversely convert an electric signal into a sound. The audio module 5270 may acquire a sound through the input device 5250, or may output a sound through the sound output device 5255 and/or the speaker and/or headphone of another electronic apparatus (e.g., the electronic apparatus 5202) which are directly or wirelessly connected to the electronic apparatus 5201.

The sensor module 5276 may detect an operating state (e.g., the power or the temperature) of the electronic apparatus 5201 or an external environmental state (e.g., a user state) and may generate an electrical signal and/or a data value corresponding to the detected state. The sensor module 5276 may include a gesture sensor, a gyro sensor, a barometric pressure sensor, a magnetic sensor, an accelerometer sensor, a grip sensor, a proximity sensor, a color sensor, an infrared (IR) sensor, a biometric sensor, a temperature sensor, a humidity sensor, and/or an illumination sensor.

The interface 5277 may support one or more designated protocols that may be used by the electronic apparatus 5201 for directly or wirelessly connection with another electronic apparatus (e.g., the electronic apparatus 5202). The interface 5277 may include a high-definition multimedia Interface (HDMI), a universal serial bus (USB) interface, a secure digital (SD) card interface, and/or an audio interface.

A connection terminal 5278 may include a connector through which the electronic apparatus 5201 may be physically connected to another electronic apparatus (e.g., the electronic apparatus 5202). The connection terminal 5278 may include an HDMI connector, an USB connector, an SD card connector, and/or an audio connector (e.g., a headphone connector).

The haptic module 5279 may convert an electrical signal into a mechanical stimulus (e.g., vibration, movement, etc.) or an electrical stimulus that a user may perceive by the tactile or kinesthetic sense. The haptic module 5279 may include a motor, a piezoelectric element, and/or an electrical stimulation device.

The camera module 5280 may capture still images and moving images. The camera module 5280 may include a lens assembly including one or more lenses, image sensors, image signal processors, and/or flashes. The lens assembly of the camera module 5280 may collect light coming from a subject to be imaged.

The power management module 5288 may manage power supplied to the electronic apparatus 5201. The power management module 8388 may be implemented as part of a power management integrated circuit (PMIC).

The battery 5289 may supply power to the components of the electronic apparatus 5201. The battery 5289 may include non-rechargeable primary cells, rechargeable secondary cells, and/or fuel cells.

The communication module 5290 may support the establishment of a direct (wired) communication channel and/or a wireless communication channel between the electronic apparatus 5201 and another electronic apparatus (e.g., the electronic apparatus 5202, the electronic apparatus 5204, or the server 5208), and may support communication through the established communication channel. The communication module 5290 may include one or more communication processors that operate independently of the processor 5220 (e.g., an application processor) and support direct communication and/or wireless communication. The communication module 5290 may include: a wireless communication module 5292 (e.g., a cellular communication module, a short-range wireless communication module, or a global navigation satellite system (GNSS) communication module); and/or a wired communication module 5294 (e.g., a local area network (LAN) communication module or a power line communication module). The communication modules 5252 and 5264 may communicate with another electronic apparatus through the first network 5298 (e.g., a short-range communication network such as Bluetooth, WiFi direct, or infrared data association (IrDA)), or the second network 5299 (e.g., a long-range communication network such as a cellular network, the Internet, or a computer network (LAN, WAN, etc.)). Such various types of communication modules may be integrated into one component (single chip, etc.) or may be implemented as a plurality of components (plural chips) separate from each other. The wireless communication module 5292 may identify and authenticate the electronic apparatus 5201 in a communication network such as the first network 5298 and/or the second network 5299 by using subscriber information (e.g., an international mobile subscriber identifier (IMSI)) stored in the subscriber identification module 5296.

The antenna module 5297 may transmit or receive signals and/or power to or from the outside (e.g., other electronic apparatuses). An antenna may include a radiator which has a conductive pattern formed on a substrate (e.g., a printed circuit board (PCB)). The antenna module 5297 may include one or a plurality of such antennas. When the antenna module 5297 include a plurality of antennas, the communication module 5290 may select one of the plurality of antennas which is suitable for a communication method used in a communication network such as the first network 5298 and/or the second network 5299. Signals and/or power may be transmitted between the communication module 5290 and another electronic apparatus through the selected antenna. In addition to the antennas, other components (e.g., a radio-frequency integrated circuit (RFIC)) may be included as part of the antenna module 5297.

Some of the components may be connected to each other and exchange signals (e.g., commands or data) by an inter-peripheral communication scheme (e.g., a bus, general purpose input and output (GPIO), serial peripheral interface (SPI), or mobile industry processor interface (MIPI)).

Commands or data may be transmitted between the electronic apparatus 5201 and the electronic apparatus 5204, that is external, through the server 5208 connected to the second network 5299. The electronic apparatuses 5202, the electronic apparatus 5204, and the electronic apparatus 5201 may be the same type of electronic apparatus or may be different types of electronic apparatuses. All or some of operations of the electronic apparatus 5201 may be executed in one or more of the electronic apparatuses 5202, the electronic apparatus 5204, and the server 5208. For example, when the electronic apparatus 5201 needs to perform a certain function or service, the electronic apparatus 5201 may request one or more other electronic apparatuses to perform a part or all of the function or service instead of performing the function or service by itself. The one or more other electronic apparatuses receiving the request may perform an additional function or service related to the request, and may transmit results thereof to the electronic apparatus 5201. To this end, cloud computing, distributed computing, and/or client-server computing techniques may be used.

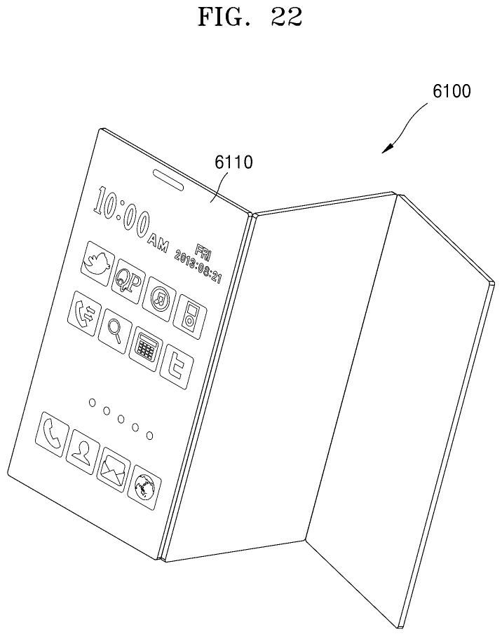

FIG. 22 is a view illustrating an example in which an electronic apparatus is applied to a mobile device 6100 according to an embodiment. The mobile device 6100 may include a display apparatus 6110 according to an embodiment. The display apparatus 6110 may include a display transfer structure 2 described with reference to FIGS. 17 to 20. The display apparatus 6110 may have a foldable structure and may be applied to a multi-foldable display. Although FIG. 22 illustrates the mobile device 6100 as a foldable display, the mobile device 6100 may be a general flat display.

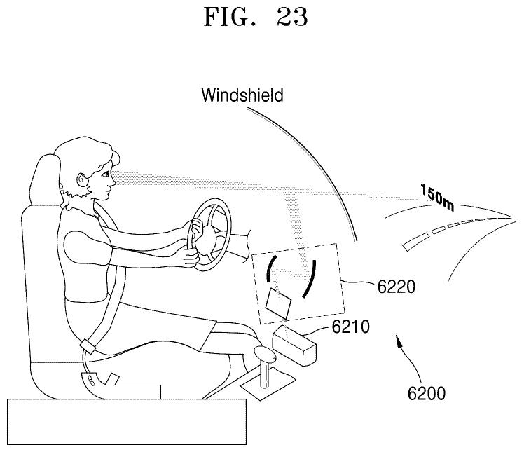

FIG. 23 is a view illustrating an example in which a display apparatus is applied to a vehicle according to an embodiment. The display apparatus may be applied to a vehicular head-up display apparatus 6200. The vehicular head-up display apparatus 6200 may include: a display apparatus 6210 provided in an region of the vehicle; and at least one optical path changing member 6220 configured to change the optical path of light such that a driver may see images generated by the display apparatus 6210.

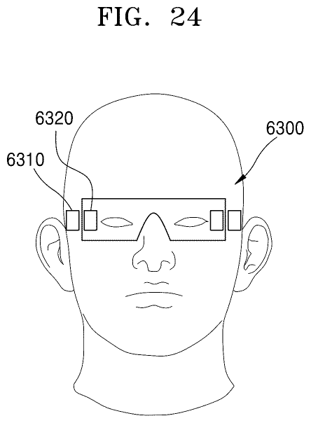

FIG. 24 is a view illustrating an example in which a display apparatus is applied to augmented or virtual reality glasses 6300 according to an embodiment. The augmented or virtual reality glasses 6300 may include: a projection system 6310 configured to form images; and one or more elements 6320 configured to guide the images from projection system 6310 into the eyes of a user. The projection system 6310 may include a display transfer structure 2 described with reference to FIGS. 17 to 20.

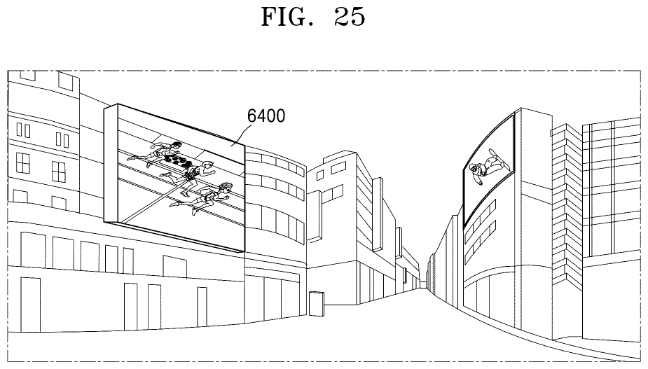

FIG. 25 is a view illustrating an example in which a display apparatus is applied to large signage 6400 according to an embodiment. The signage 6400 may be used for outdoor advertisement using a digital information display and may control advertisement content and the like through a communication network. For example, the signage 6400 may be implemented through the electronic apparatus 5201 described with reference to FIG. 21.

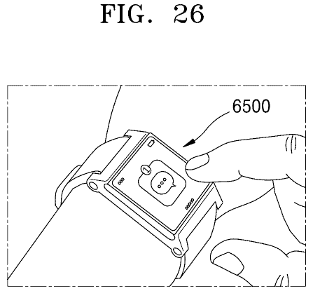

FIG. 26 is a view illustrating an example in which a display apparatus is applied to a wearable display 6500 according to an embodiment. The wearable display 6500 may include the display transfer structure 2 described with reference to FIGS. 17 to 20 and may be implemented through the electronic apparatus 5201 described with reference to FIG. 21.

The display apparatuses of the embodiments may be applied to various products such as a rollable TV and a stretchable display.

As described above, according to the one or more of the above embodiments, the micro semiconductor chips 1 may be configured to reduce the possibility of scratches or damage during a transfer operation.

The micro semiconductor chips 1 may improve transfer yield, and the display apparatus 3 may be manufactured using the micro semiconductor chips 1 with high productivity.

It should be understood that the example embodiments described herein should be considered in a descriptive sense only and not for purposes of limitation. Features or aspects within each embodiment should typically be considered as available for other similar features or aspects in other embodiments. While one or more non-limiting example embodiments have been described with reference to the figures, it will be understood by those of ordinary skill in the art that various changes in form and details may be made therein without departing from the spirit and scope of the present disclosure.

What is claimed is:

1. A micro semiconductor chip comprising:
a semiconductor multilayer; and
at least one electrode on at least one surface of the semiconductor multilayer,
wherein the semiconductor multilayer has an n-polygonal planar shape and n rounded corners, wherein n is an integer greater than or equal to 3.

2. The micro semiconductor chip of claim 1, wherein the n rounded corners have a radius of curvature of 0.5 μm or more.

3. The micro semiconductor chip of claim 1, wherein the n rounded corners have a radius of curvature that is less than 50% of a length of one side of the semiconductor multilayer.

4. The micro semiconductor chip of claim 1, wherein the semiconductor multilayer comprises a first-type semiconductor layer, an active layer, and a second-type semiconductor layer that are sequentially stacked in a first direction, and
wherein the n-polygonal planar shape of the semiconductor multilayer is a shape of the semiconductor multilayer in the first direction.

5. The micro semiconductor chip of claim 4, wherein a planar size of the first-type semiconductor layer is greater than a planar size of the second-type semiconductor layer.

6. The micro semiconductor chip of claim 5, wherein the first-type semiconductor layer is thicker than the second-type semiconductor layer.

7. The micro semiconductor chip of claim 4, wherein the first-type semiconductor layer comprises the n rounded corners.

8. The micro semiconductor chip of claim 7, wherein the active layer and the second-type semiconductor layer comprise the n rounded corners.

9. The micro semiconductor chip of claim 4, wherein the first-type semiconductor layer and the second-type semiconductor layer have a same planar size as each other.

10. The micro semiconductor chip of claim 1, wherein the at least one electrode comprises a first electrode and a second electrode that are spaced apart from each other on one surface of the semiconductor multilayer.

11. The micro semiconductor chip of claim 1, wherein the at least one electrode comprises a first electrode on a first surface of the semiconductor multilayer and a second electrode on a second surface of the semiconductor multilayer, opposite of the first surface.

12. The micro semiconductor chip of claim 1, wherein a length of one side of the micro semiconductor chip is 100 μm or less.

13. A display transfer structure comprising:
a substrate comprising a plurality of recesses that are spaced apart from each other; and
a plurality of micro semiconductor chips in the plurality of recesses,
wherein each of the plurality of micro semiconductor chips comprises:
a semiconductor multilayer; and
at least one electrode on at least one surface of the semiconductor multilayer, and
wherein the semiconductor multilayer has an n-polygonal planar shape and n rounded corners, wherein n is an integer greater than or equal to 3.

14. The display transfer structure of claim 13, wherein each of the plurality of recesses has a corner shape that is different from a corner shape of the n rounded corners of the semiconductor multilayer of the plurality of micro semiconductor chips.

15. The display transfer structure of claim 13, wherein the n rounded corners have a radius of curvature of 0.5 μm or more.

16. The display transfer structure of claim 13, wherein the n rounded corners have a radius of curvature that is less than 50% of a length of one side of the semiconductor multilayer.

17. The display transfer structure of claim 13, wherein the semiconductor multilayer comprises a first-type semiconductor layer, an active layer, and a second-type semiconductor layer that are sequentially stacked in a first direction, and
wherein the n-polygonal planar shape of the semiconductor multilayer is a shape of the semiconductor multilayer in the first direction.

18. A display apparatus comprising:
a driving circuit board; and
a plurality of micro semiconductor chips spaced apart from each other on the driving circuit board,
wherein each of the plurality of micro semiconductor chips comprises:
a semiconductor multilayer; and
at least one electrode on at least one surface of the semiconductor multilayer, and
wherein the semiconductor multilayer has an n-polygonal planar shape and n rounded corners, wherein n is an integer greater than or equal to 3.

19. The display apparatus of claim 18, wherein the n rounded corners have a radius of curvature of 0.5 μm or more.

20. The display apparatus of claim 18, wherein the n rounded corners have a radius of curvature that is less than 50% of a length of one side of the semiconductor multilayer.
